(19) United States
(12) Patent Application Publication
(10) Pub. No.: US 2010/0327915 A1
(43) Pub. Date: Dec. 30, 2010

(54) SEMICONDUCTOR DEVICE AND METHOD FOR RESETTING THE SAME

(76) Inventors: Tsuyoshi Imanaka, Osaka (JP); Noriyuki Shimazu, Osaka (JP)

Correspondence Address: MCDERMOTT WILL & EMERY LLP, 600 13TH STREET, NW, WASHINGTON, DC, 20005-3096, US

(21) Appl. No.: 12/520,669

(22) PCT Filed: Sep. 9, 2008
(86) PCT No.: PCT/JP2008/002490

§ 371 Date: Jun. 22, 2009

(30) Foreign Application Priority Data
Feb. 6, 2008 (JP) 2008-026876

(51) Int. Cl. H03K 5/153

(52) U.S. Cl. 327/80

(57) ABSTRACT

An object is to provide a semiconductor device within which a signal which can be used as a reset signal or a mode signal is produced at an arbitrary timing to reduce the number of pads of the semiconductor device. To achieve the object, in a semiconductor device (10), first and second pads (101, 102) are respectively supplied with an external supply voltage and a ground potential. A signal generating circuit (12) outputs a signal at a predetermined logic level when the voltage supplied to the first pad (101) reaches a predetermined voltage higher than a voltage supplied to the first pad (101) during a normal operation of the semiconductor device (10).

### TECHNICAL FIELD

The present invention relates to a semiconductor device, and specifically to the reduction of the number of pads of the semiconductor device.

### BACKGROUND ART

Generally, a semiconductor device such as an LSI circuit can be reset by supplying a reset signal and can be switched accordingly between operational modes such as a normal mode and a test mode by supplying a mode signal. Such control signals are distributed through dedicated pads to a number of internal circuits. Therefore, a general semiconductor device requires a large amount of wiring resources for routing control signals input through pads to every part of the device and a number of buffers for increasing the fan-out of the control signals.

The chip size of a semiconductor device is determined by an internal parameter and a pad parameter. The internal parameter is understood to mean that the area of an internal circuit determines the chip size. The pad parameter is understood to mean that the number or the size of pads determines the chip size. The above-mentioned general semiconductor device has a large amount of wiring resources and a number of buffers, and further has a plurality of pads for receiving control signals, which results in a relatively large chip size of the semiconductor device. To reduce the chip size of a semiconductor device, it is required to reduce the number of pads while reducing the area of an internal circuit.

Specifically, an advance in recent years in technologies for miniaturizing a transistor reduces the area of an internal circuit, whereas it is difficult to reduce the pad pitch due to a limitation of assembly technique, a limitation of jigs for wafer level burn-in, and the like. Therefore, the number of cases where the pad parameter determines the chip size is increasing. Accordingly, to reduce the chip size of a semiconductor device, it is important in particular to reduce the number of pads. Conventionally, before a system starts a stabile operation, a reset signal is generated within the system to dispense with a pad for receiving the reset signal (see, for example, Patent Document 1).
[Patent Document 1] Japanese Unexamined Patent Publication H09-181586 (pp. 2-3, FIG. 2)

### DISCLOSURE OF INVENTION

### Problems to be Solved by the Invention

The above-mentioned reset signal generating circuit outputs a reset signal at the time of turning on the power to a semiconductor device, and does not output a reset signal after the stabilization of a supply voltage. Therefore, to switch the semiconductor device from a normal mode to another mode, it is still required to input a mode signal to a dedicated pad. Moreover, through the above-mentioned reset signal generating circuit, a through current flows during a normal operation of the semiconductor device, resulting in increased power consumption.

In view of the above-mentioned problems, an object of the present invention is to generate a signal which can be used as a reset signal or a mode signal within a semiconductor device at an arbitrary timing for reducing the number of pads of the semiconductor device. Another object of the present invention is to prevent a through current from flowing through a circuit for generating such a signal during the normal operation of the semiconductor device. Still another object of the present invention is to provide a method for resetting such a semiconductor device having a reduced number of pads.

### Means for Solving the Problems

To achieve the above-mentioned object, an approach taken by the present invention is that a semiconductor device having a first pad for receiving an external supply generating circuit for outputting a signal at a predetermined logic level when a voltage supplied to the first pad reaches a predetermined voltage higher than a voltage supplied to the first pad during a normal operation of the semiconductor device. With this configuration, changing the external supply voltage supplied to the semiconductor device enables a signal at a predetermined logic level to be generated within the semiconductor device. This dispenses with a pad for externally receiving the signal, thereby reducing the number of pads.

Specifically, the signal generating circuit includes: a resistive load whose one end is supplied with the external supply voltage through the first pad; and a transistor having a source or emitter supplied with the ground potential through the second pad, a drain or collector connected to the other end of the resistive load, and a gate or base supplied with the external supply voltage through the first pad, a threshold voltage of the transistor corresponding to the predetermined voltage, and the signal generating circuit outputs a voltage at a node between the resistive load and the transistor as the signal. Moreover, the signal generating circuit further includes: a second resistive load whose one end is supplied with the ground potential through the second pad; and a second transistor having a source or emitter supplied with the external supply voltage through the first pad, a drain or collector connected to the other end of the second resistive load, and a gate or base connected to the node between the resistive load and the transistor, and the signal generating circuit outputs a voltage at a node between the second resistive load and the second transistor, in place of the node between the resistive load and the transistor, as the signal. Alternatively, the signal generating circuit includes: a resistive load whose one end is supplied with the external supply voltage through the first pad; and a plurality of transistors connected in series between the other end of the resistive load and the ground potential supplied through the second pad, and the signal generating circuit outputs a voltage at a node between the resistive load and the plurality of transistors as the signal. Here, any one of the plurality of transistors has a drain or collector connected to the other end of the resistive load and a gate or base supplied with the external supply voltage through the first pad, the others are diode-connected, and any one of the diode-connected transistors has a source or emitter supplied with the ground potential through the second pad. Through the signal generating circuits having these configurations, no through current flows during the normal operation of the semiconductor device.

The semiconductor device may have a second signal generating circuit for outputting a signal at a predetermined logic level when the voltage supplied to the first pad reaches a voltage higher than the predetermined voltage. Alternatively, the semiconductor device may have a third pad for receiving a second external supply voltage, and a second signal generating circuit for outputting a signal at a predetermined logic level when a voltage supplied to the third pad reaches a predetermined voltage higher than a voltage supplied to the third pad during the normal operation of the semiconductor device. With these configurations, the number of types of signals generated within the semiconductor device can be increased.

Moreover, the semiconductor device may have a low-pass filter for removing a high frequency component of the signal output from the signal generating circuit. With this configuration, a noise component or the like in the generated signal can be removed.

Moreover, the semiconductor device may have a third pad for outputting the signal output from the signal generating circuit outside the semiconductor device. With this configuration, monitoring the signal output from the third pad makes it possible to easily check whether or not a predetermined voltage is supplied to an internal circuit of the semiconductor device.

The semiconductor device may switch operational modes or reset an internal circuit according to the signal output from the signal generating circuit.

Moreover, according to a method for resetting the semiconductor device, a voltage higher than the predetermined voltage is supplied to the first pad to cause the signal generating circuit to output the signal for resetting an internal circuit. With this method, controlling the external supply voltage enables the semiconductor device to be reset at an arbitrary timing.

### Effects of the invention

According to the present invention, a signal which can be used as a reset signal or a mode signal is generated within a semiconductor device at an arbitrary timing to reduce the number of pads of the semiconductor device. Moreover, during a normal operation of the semiconductor device, no through current flows through a signal generating circuit for generating such a signal, and thus power consumption can be suppressed. Therefore, it is possible to reduce the size and save the power of the semiconductor device.

### BRIEF DESCRIPTION OF DRAWINGS

FIG. 1 is a block diagram of a semiconductor device according to Embodiment 1.

FIG. 2 is a view showing a circuit configuration of a signal generating circuit according to an embodiment.

FIG. 3 is a graph showing an operating characteristic of the signal generating circuit of FIG. 2.

FIG. 4 is a view showing a circuit configuration of a signal generating circuit according to another embodiment.

FIG. 5 is a view showing a circuit configuration of a signal generating circuit according to still another embodiment.

FIG. 6 is a graph showing an operating characteristic of the signal generating circuit of FIG. 5.

FIG. 7 is a graph showing the relationship between an external supply voltage and a reset signal.

FIG. 8 is a block diagram of a semiconductor device according to Embodiment 2.

FIG. 9 is a block diagram of a semiconductor device according to Embodiment 3.

FIG. 10 is a block diagram of a semiconductor device according to Embodiment 4.

FIG. 11 is a graph showing operational characteristics of two types of signal generating circuits in the semiconductor device of FIG. 10.

FIG. 12 is a block diagram of a semiconductor device according to Embodiment 5.

### DESCRIPTION OF REFERENCE NUMERALS

10 Semiconductor Device
101 Pad (First Pad)
102 Pad (Second Pad)
103 Pad (Third Pad)
104 Pad (Third Pad)
11 Internal Circuit
12 Signal Generating Circuit
121 Resistive Load
122 NMOS Transistor
123 NMOS Transistor
124 NMOS Transistor
125 Resistive Load (Second Resistive Load)
126 PMOS Transistor (Second Transistor)
13 Low-Pass Filter

14 Signal Generating Circuit (Second Signal Generating Circuit)

### Best Mode for Carrying Out the Invention

Best mode for carrying out the present invention will be described below with reference to the drawings.

### Embodiment 1

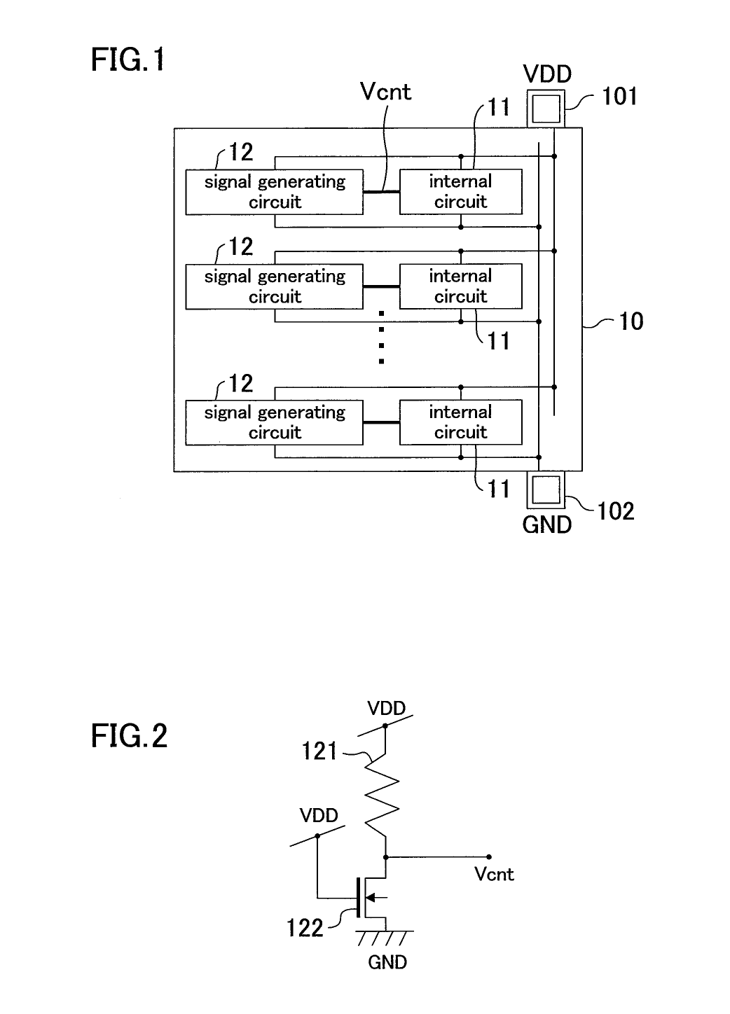

FIG. 1 shows a configuration of a semiconductor device according to Embodiment 1. A semiconductor device 10 according to the present embodiment includes a plurality of internal circuits 11 and a plurality of signal generating circuits 12. The internal circuits 11 and the signal generating circuits 12 are supplied with an external supply voltage VDD and a ground potential GND respectively through pads 101 and 102. When the external supply voltage VDD supplied to the pad 101 reaches a predetermined voltage higher than a voltage supplied to the pad 101 during a normal operation of the semiconductor device 10, each signal generating circuit 12 outputs a signal Vcnt at a predetermined logic level. Each internal circuit 11 performs an intended operation (for example, a test operation) according to the input signal Vcnt.

FIG. 2 shows a circuit configuration of the signal generating circuit 12 according to an embodiment. This signal generating circuit 12 can include a resistive load 121 and an NMOS transistor 122. To one end of the resistive load 121, the external supply voltage VDD is supplied through the pad 101. The resistive load 121 can be realized by using, for example, channel resistance of a PMOS transistor as well as a resistive element. The NMOS transistor 122 has a source supplied with the ground potential GND through the pad 102, a drain connected to the other end of the resistive load 121, and a gate supplied with the external supply voltage VDD through the pad 101. A voltage at a node between the resistive load 121 and the NMOS transistor 122 is to be the signal Vcnt. It should be noted that the NMOS transistor 122 is a transistor having a threshold voltage higher than that of an ordinary NMOS transistor constituting other logic circuits, specifically, a transistor having a threshold voltage corresponding to the above-mentioned predetermined voltage.

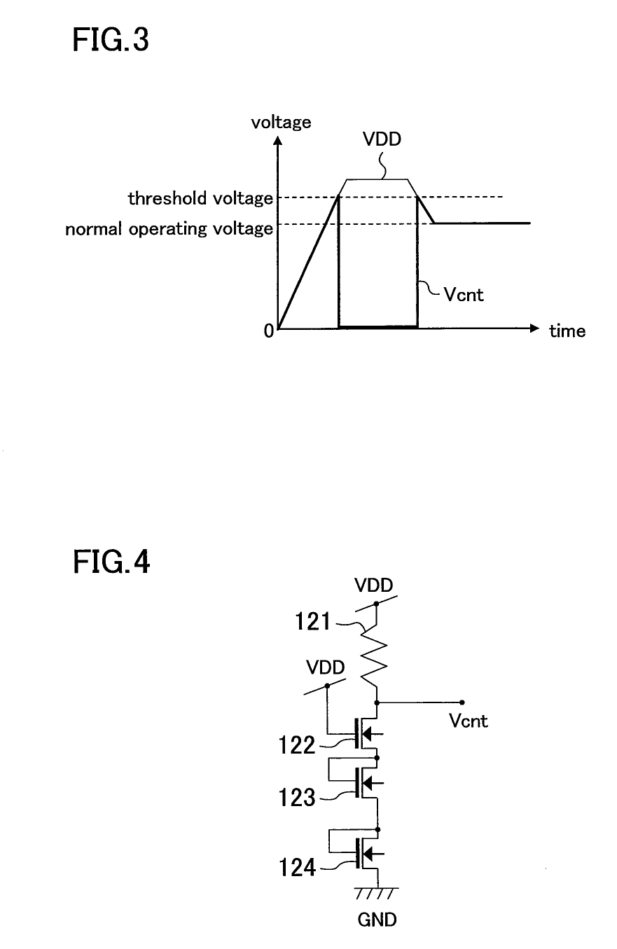

With reference to the graph of FIG. 3, the operation of the signal generating circuit 12 of FIG. 2 will be explained. While the external supply voltage VDD gradually increases from zero up to the threshold voltage of the NMOS transistor 122, the NMOS transistor 122 is in the OFF state. Therefore, the signal Vcnt is equal to the voltage VDD, and thus at the logic level “H.” When the voltage VDD further increases and exceeds the threshold voltage, the NMOS transistor 122 is turned on. This causes the signal Vcnt to transition to the ground potential GND, i.e., the logic level “L.” After that, when the voltage VDD drops below the threshold voltage, the NMOS transistor 122 is turned off. Therefore, the signal Vcnt becomes equal to the voltage VDD, and thus transitions to the logic level “H.” Then, in the stationary state in which the voltage VDD is a normal operating voltage, the NMOS transistor 122 is in the OFF state, and thus no through current flows.

In the case where the NMOS transistor 122 is a transistor having a threshold voltage corresponding to that of an ordinary NMOS transistor constituting other logic circuits, the signal generating circuit 12 may be configured as follows. FIG. 4 shows a circuit configuration of a signal generating circuit 12 according to another embodiment. This signal generating circuit 12 is obtained by inserting diode-connected NMOS transistors 123 and 124 between the NMOS transistor 122 and the ground potential GND of the signal generating circuit 12 of FIG. 2. The number of NMOS transistors to be inserted between the NMOS transistor 122 and the ground potential GND is accordingly chosen, so that also this signal generating circuit 12 operates as shown in the graph of FIG. 3.

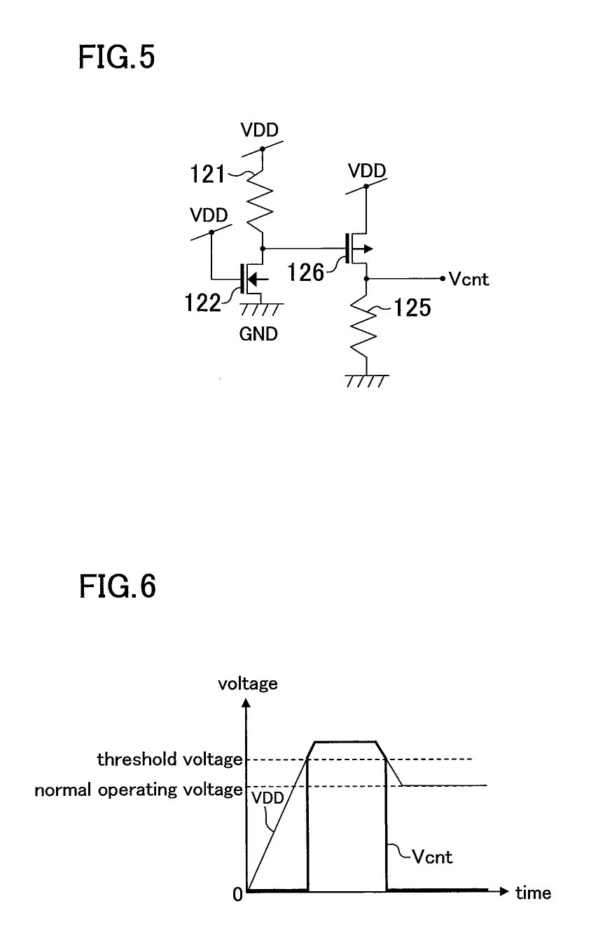

To cause the signal generating circuit 12 to output the signal Vcnt at the logic level “H” when the external supply voltage VDD reaches the above-mentioned predetermined voltage, an inverter circuit may be provided at an output side of the signal generating circuit 12 of FIG. 2 or FIG. 4. Alternatively, the signal generating circuit 12 may be configured as follows. FIG. 5 shows a circuit configuration of a signal generating circuit 12 according to still another embodiment. This signal generating circuit 12 is obtained by adding a resistive load 125 and a PMOS transistor 126 to the signal generating circuit 12 of FIG. 2. To one end of the resistive load 125, the ground potential GND is supplied through the pad 102. The resistive load 125 can be realized by using, for example, channel resistance of an NMOS transistor as well as a resistive element. The PMOS transistor 126 has a source supplied with the external supply voltage VDD through the pad 101, a drain connected to the other end of the resistive load 125, and a gate connected to the node between the resistive load 121 and the NMOS transistor 122. A voltage at a node between the resistive load 125 and the PMOS transistor 126 is to be the signal Vcnt.

With reference to the graph of FIG. 6, the operation of the signal generating circuit 12 of FIG. 5 will be explained. While the external supply voltage VDD gradually increases from zero up to the threshold voltage of the NMOS transistor 122, a voltage at the logic level “H” is applied to the gate of the PMOS transistor 126, and thus the PMOS transistor 126 is in the OFF state. Therefore, the signal Vcnt is the ground potential GND, i.e., at the logic level “L.” When the voltage VDD further increases and exceeds the threshold voltage, a voltage at the logic level “L” is applied to the gate of the PMOS transistor 126, and thus the PMOS transistor 126 is turned on. Therefore, the signal Vcnt becomes equal to the voltage VDD, and thus transitions to the logic level “H.” After that, when the voltage VDD drops below the threshold voltage, a voltage at the logic level “H” is applied to the gate of the PMOS transistor 126, and thus the PMOS transistor 126 is turned off. This causes the signal Vcnt to transition to the ground potential GND, i.e., the logic level “L.” In the subsequent stationary state, the NMOS transistor 122 and the PMOS transistor 126 are both in the OFF state, and thus no through current flows.

The signal Vcnt can be used for switching the semiconductor device 10 to a scan test mode, a burn-in test mode, or the like. For example, in the case where the signal Vcnt is used for the switching to the bum-in test mode, the signal generating circuit 12 is configured to generate a signal Vcnt at a predetermined voltage between the normal operating voltage and a burn-in test voltage. Therefore, for the burn-in test on the semiconductor device 10, the burn-in test voltage is supplied as the external supply voltage VDD to the semiconductor device 10, which enables the semiconductor device 10 to be switched to the burn-in test mode. Alternatively, if the semiconductor device 10 is provided for a high-grade mode in which an external supply voltage VDD higher than a normal voltage is supplied, for example, to increase an operating frequency or to activate a specific internal circuit, the signal Vcnt can be used as a signal for selecting such a high-grade mode.

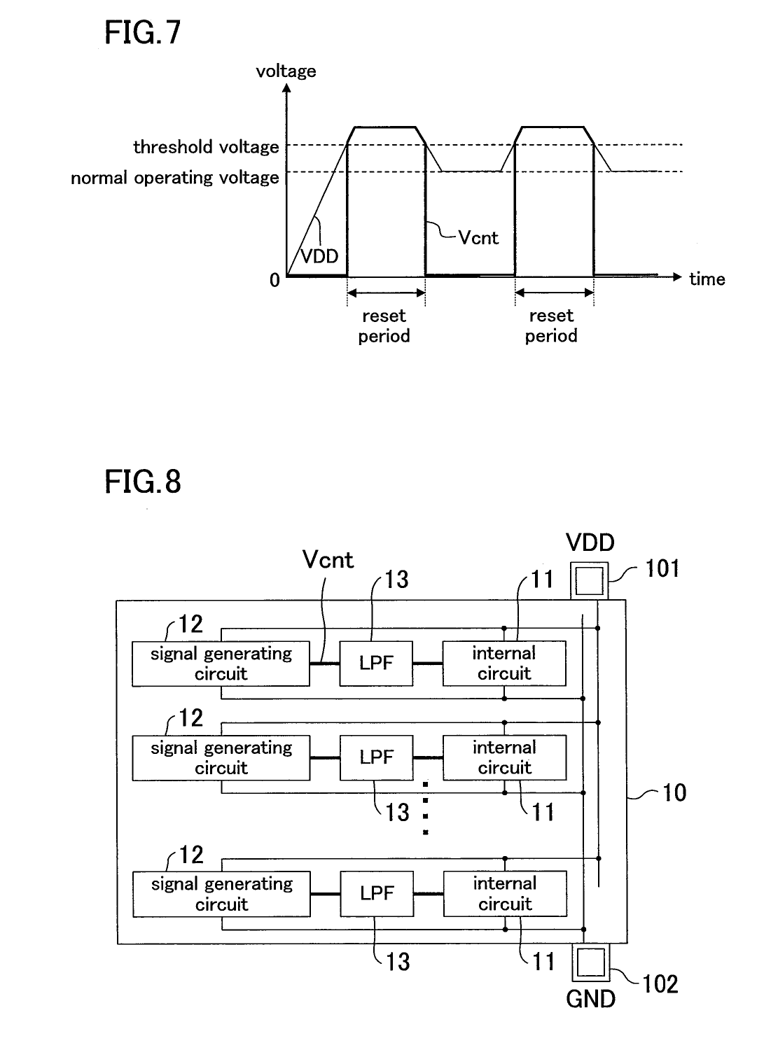

Alternatively, the signal Vcnt can be used as a reset signal of the semiconductor device 10. FIG. 7 shows the relationship between the external supply voltage VDD and a reset signal Vcnt, where the signal Vcnt is used as the reset signal. For resetting the internal circuit 11 at the time of activating the semiconductor device 10, the voltage VDD is increased to be higher than the threshold voltage. Therefore, while the voltage VDD is higher than the threshold voltage, the reset signal Vcnt is at the logic level “H,” and the internal circuit 11 is reset. After that, when the voltage VDD drops down to the normal operating voltage, the reset signal Vcnt transitions to the logic level “L,” and the reset of the internal circuit 11 is released. Likewise, for resetting the internal circuit 11 during the normal operation, the voltage VDD is increased to be higher than the threshold voltage. Therefore, while the voltage VDD is higher than the threshold voltage, the internal circuit 11 is reset. After that, when the voltage VDD drops to the normal operating voltage, the reset of the internal circuit 11 is released.

As described above, according to the present embodiment, the external supply voltage VDD supplied to the semiconductor device 10 is controlled, which enables the signal Vcnt for controlling the switching between modes or the resetting to be generated within the semiconductor device 10. This dispenses with a pad for externally receiving the signal Vent, reducing the number of pads. Moreover, no through current flows through the signal generating circuit 12 while the semiconductor device 10 is in the stationary state, and thus power consumption does not increase. Furthermore, the internal circuits 11 are each provided with a signal generating circuit 12, and thus a large amount of wiring resources and buffers can be reduced, which enables the wiring resources to be used for the other purposes. Even if a number of signal generating circuits 12 are provided, the chip size of the semiconductor device 10 does not especially increase, since the signal generating circuit 12 can be realized with a very simple configuration.

It should be noted that in the signal generating circuits 12 of FIGS. 2, 4 and 5, each of the MOS transistors may be substituted with bipolar transistors.

### Embodiment 2

FIG. 8 shows a configuration of a semiconductor device according to Embodiment 2. A semiconductor device 10 according to the present embodiment is obtained by inserting a low-pass filter 13 between each internal circuit 11 and each signal generating circuit 12 of the semiconductor device 10 of Embodiment 1. That is, the low-pass filter 13 removes a high frequency component of the signal Vent output from the signal generating circuit 12. The low-pass filter 13 can include, for example, a resistive element and a capacitative element. According to the present embodiment, even if influence of noise or the like momentarily increases the external supply voltage VDD and destabilizes the signal Vcnt, a stabile signal without the influence of noise or the like can be input to the internal circuit 11.

### Embodiment 3

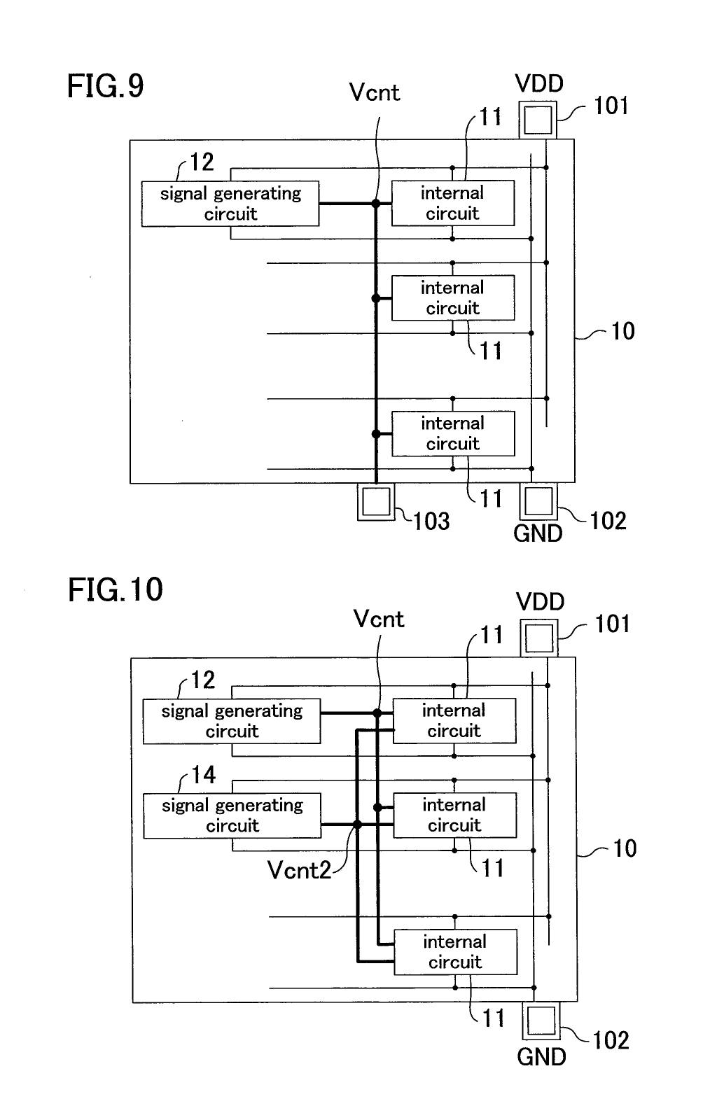

FIG. 9 shows a configuration of a semiconductor device according to Embodiment 3. A semiconductor device 10 according to the present embodiment is obtained by modifying the semiconductor device 10 of Embodiment 1 such that the signal

Vent is input from one signal generating circuit 12 to the internal circuits 11. A wire for transmitting the signal Vcnt is routed in this way, thereby parasitic resistance and parasitic capacitance of the wire form a low-pass filter, resulting in the same effect as in Embodiment 2.

Moreover, the semiconductor device 10 according to the present embodiment includes a pad 103 for outputting the signal Vcnt outside the device. The pad 103 can be used as a supply voltage monitor. For example, in the case where the semiconductor device 10 is operated in the above-mentioned high-grade mode, a voltage at the pad 101 may be measured with the hope of externally checking whether or not the external supply voltage VDD required for the high-grade mode is supplied to the semiconductor device 10. However, a voltage drop across the internal circuit 11 cannot be measured, and thus it is not possible to know whether or not the semiconductor device 10 operates in the high-grade mode. In contrast, monitoring a signal output from the pad 103 makes it possible to easily know whether or not the semiconductor device 10 operates in the high-grade mode. It should be noted that the semiconductor device 10 according to the other embodiments may be provided with the pad 103.

### Embodiment 4

FIG. 10 shows a configuration of a semiconductor device according to Embodiment 4. A semiconductor device 10 according to the present embodiment includes a plurality of internal circuits 11 and two types of signal generating circuits 12 and 14. The internal circuits 11 and the signal generating circuits 12 and 14 are supplied with the external supply voltage VDD and the ground potential GND respectively through pads 101 and 102. When the external supply voltage VDD supplied to the pad 101 reaches a predetermined voltage higher than a voltage supplied to the pad 101 during the normal operation of the semiconductor device 10, the signal generating circuit 12 outputs a signal Vcnt at a predetermined logic level. When the external supply voltage VDD supplied to the pad 101 reaches a voltage higher than the above-mentioned predetermined voltage, the signal generating circuit 14 outputs a signal Vcnt2 at a predetermined logic level. Each internal circuit 11 performs an intended operation (for example, a test operation) according to the input signals Vcnt and Vcnt2. It should be noted that specific circuit configurations of the signal generating circuits 12 and 14 are as shown in FIGS. 2, 4, and 5.

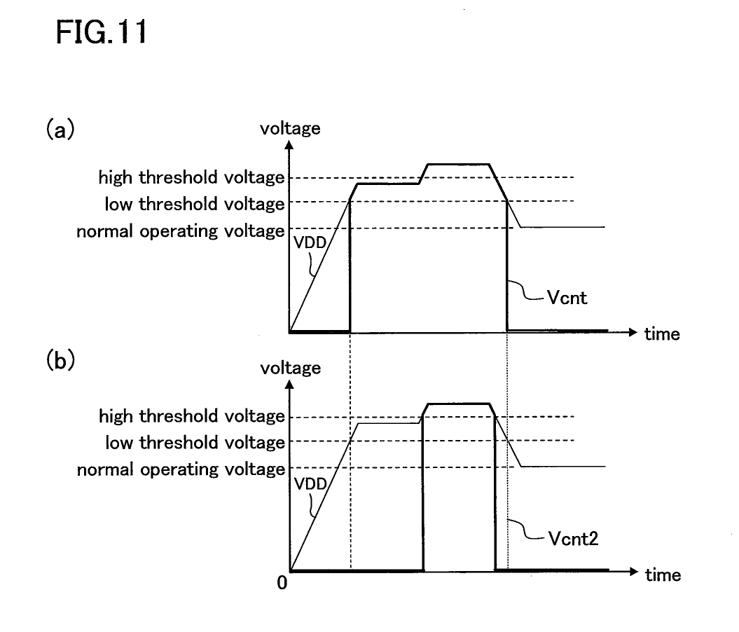

With reference to the graph of FIG. 11, the operations of the signal generating circuits 12 and 14 will be explained. FIG. 11(a) shows the operation of the signal generating circuit 12. FIG. 11(b) shows the operation of the signal generating circuit 14. It should be noted that the signal generating circuits 12 and 14 are each configured as shown in FIG. 5. While the external supply voltage VDD gradually increases from zero up to a threshold voltage (i.e., a low threshold voltage) of the NMOS transistor 122 in the signal generating circuit 12, a voltage at the logic level “H” is applied to the gate of each of the PMOS transistors 126 in the signal generating circuit 12 and 14, and thus these PMOS transistors 126 are in the OFF state. Therefore, the signals Vcnt and Vcnt2 are the ground potential GND, i.e., at the logic level “L.” When the voltage VDD further increases and exceeds the low threshold voltage, a voltage at the logic level “L” is applied to the gate of the PMOS transistor 126 in the signal generating circuit 12, and thus this PMOS transistor 126 is turned on. Therefore, the signal Vent becomes equal to the voltage VDD, and thus transitions to the logic level “H.” Meanwhile, until the voltage VDD reaches a threshold voltage (i.e., a high threshold voltage) of the NMOS transistor 122 in the signal generating circuit 14, the voltage at the logic level “H” is continuously applied to the gate of the PMOS transistor 126 in the signal generating circuit 14, and thus this PMOS transistor 126 remains in the OFF state. Therefore, the signal Vcnt2 remains at the logic level “L.” When the voltage VDD further increases and exceeds the high threshold voltage, a voltage at the logic level “L” is applied to the gate of the PMOS transistor 126 in the signal generating circuit 14, and thus this PMOS transistor 126 is turned on. Therefore, the signal Vcnt2 becomes equal to the voltage VDD, and thus transitions to the logic level “H.”

After that, when the voltage VDD drops below the high threshold voltage, a voltage at the logic level “H” is applied to the gate of the PMOS transistor 126 in the signal generating circuit 14, and thus this PMOS transistor 126 is turned off. This causes the signal Vcnt2 to transition to the ground potential GND, i.e., the logic level “L.” Meanwhile, until the voltage VDD drops below the low threshold voltage, the voltage at the logic level “L” is continuously applied to the gate of the PMOS transistor 126 in the signal generating circuit 12, and thus this PMOS transistor 126 remains in the on state. Therefore, the signal Vcnt remains at the logic level “H.” When the voltage VDD further drops below low threshold voltage, a voltage at the logic level “H” is applied to the gate of the PMOS transistor 126 in the signal generating circuit 12, and thus this PMOS transistor 126 is turned off This causes the signal Vcnt to transition to the ground potential GND, i.e., the logic level “L.”

As described above, according to the present embodiment, minutely controlling the external supply voltage VDD supplied to the semiconductor device 10 enables the two types of signals Vcnt and Vcnt2 to be generated within the semiconductor device 10. This dispenses with pads for externally receiving the signals Vcnt and Vcnt2, further reducing the number of pads as compared to Embodiment 1.

It should be noted that providing more types of signal generating circuits to more minutely control the external supply voltage VDD enables more than two types of signals to be generated within the device.

### Embodiment 5

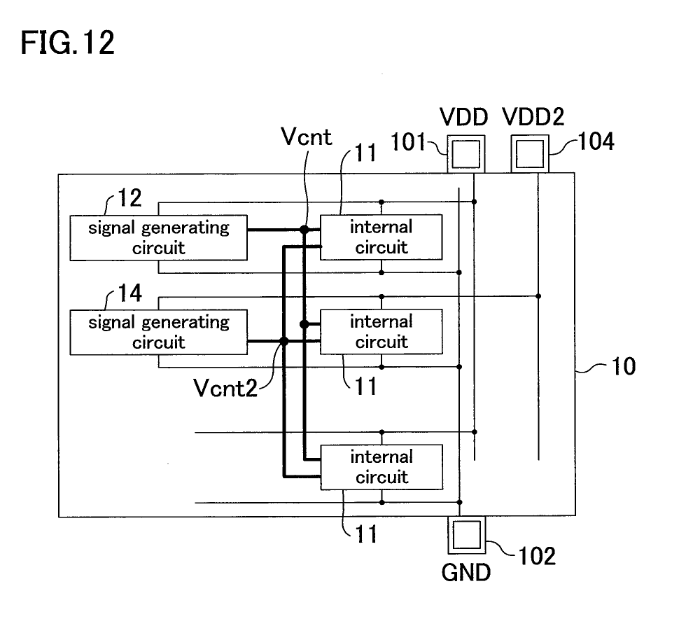

FIG. 12 shows a configuration of a semiconductor device according to Embodiment 5. A semiconductor device 10 according to the present embodiment includes a plurality of internal circuits 11 and two types of signal generating circuits 12 and 14. The signal generating circuit 12 is supplies with the external supply voltage VDD and the ground potential GND respectively through pads 101 and 102. When the external supply voltage VDD supplied to the pad 101 reaches a predetermined voltage higher than a voltage supplied to the pad 101 during the normal operation of the semiconductor device 10, the signal generating circuit 12 outputs a signal Vcnt at a predetermined logic level. Meanwhile, the signal generating circuit 14 is supplied with an external supply voltage VDD2 and the ground potential GND respectively through a pad 104 and the pad 102. When the external supply voltage VDD2 supplied to the pad 104 reaches a predetermined voltage higher than a voltage supplied to the pad 104 during the normal operation of the semiconductor device 10, the signal generating circuit 14 outputs a signal Vcnt2 at a predetermined logic level. Each internal circuit 11 is commonly supplied with the ground potential GND through the pad 102, and supplied with one of the external supply voltages VDD and VDD2 through one of the pads 101 and 104. Each internal circuit 11 performs an intended operation (for example, a test operation) according to the input signals Vcnt and Vcnt2. It should be noted that the illustration of a level shift circuit between different power sources is omitted.

Specific circuit configurations of the signal generating circuits 12 and 14 are as shown in FIGS. 2, 4, and 5. It should be noted that since the external supply voltages VDD and VDD2 are independent of each other, the threshold voltages of the NMOS transistors 122 in the signal generating circuits 12 and 14 may also be set independently of each other.

As described above, according to the present embodiment, the two types of external supply voltages VDD and VDD2 supplied to the semiconductor device 10 are controlled independently of each other, which enables two types of signals Vcnt and Vcnt2 to be generated independently of each other within the semiconductor device 10. This dispenses with pads for externally receiving the signals Vcnt and Vcnt2, reducing the number of pads.

### INDUSTRIAL APPLICABILITY

A semiconductor device according to the present invention enables a signal which can be used as a reset signal or a mode signal to be generated within the semiconductor device at an arbitrary timing for reducing the number of pads of the semiconductor device, and thus is useful for electronic equipment requiring small size and low power consumption.

1. A semiconductor device having a first pad for receiving an external supply voltage, and a second pad for receiving a ground potential, the semiconductor device comprising
a signal generating circuit for outputting a signal at a predetermined logic level when a voltage supplied to the first pad reaches a predetermined voltage higher than a voltage supplied to the first pad during a normal operation of the semiconductor device.

2. The semiconductor device of claim 1, wherein
the signal generating circuit includes:
a resistive load whose one end is supplied with the external supply voltage through the first pad; and
a transistor having a source or emitter supplied with the ground potential through the second pad, a drain or collector connected to the other end of the resistive load, and a gate or base supplied with the external supply voltage through the first pad, a threshold voltage of the transistor corresponding to the predetermined voltage, and
the signal generating circuit outputs a voltage at a node between the resistive load and the transistor as the signal.

3. The semiconductor device of claim 2, wherein
the signal generating circuit further includes:
a second resistive load whose one end is supplied with the ground potential through the second pad; and
a second transistor having a source or emitter supplied with the external supply voltage through the first pad, a drain or collector connected to the other end of the second resistive load, and a gate or base connected to the node between the resistive load and the transistor, and
the signal generating circuit outputs a voltage at a node between the second resistive load and the second transistor, in place of the node between the resistive load and the transistor, as the signal.

4. The semiconductor device of claim 1, wherein
the signal generating circuit includes:
a resistive load whose one end is supplied with the external supply voltage through the first pad; and
a plurality of transistors connected in series between the other end of the resistive load and the ground potential supplied through the second pad,
the signal generating circuit outputs a voltage at a node between the resistive load and the plurality of transistors as the signal, and
any one of the plurality of transistors has a drain or collector connected to the other end of the resistive load and a gate or base supplied with the external supply voltage through the first pad, the others are diode-connected, and any one of the diode-connected transistors has a source or emitter supplied with the ground potential through the second pad.

5. The semiconductor device of claim 1, further comprising a second signal generating circuit for outputting a signal at a predetermined logic level when the voltage supplied to the first pad reaches a voltage higher than the predetermined voltage.

6. The semiconductor device of claim 1, further comprising:
a third pad for receiving a second external supply voltage; and
a second signal generating circuit for outputting a signal at a predetermined logic level when a voltage supplied to the third pad reaches a predetermined voltage higher than a voltage supplied to the third pad during the normal operation of the semiconductor device.

7. The semiconductor device of claim 1, further comprising a low-pass filter for removing a high frequency component of the signal output from the signal generating circuit.

8. The semiconductor device of claim 1, further comprising a third pad for outputting the signal output from the signal generating circuit outside the semiconductor device.

9. The semiconductor device o claim 1, wherein operational modes are switched according to the signal output from the signal generating circuit.

10. The semiconductor device of claim 1, wherein an internal circuit is reset according to the signal output from the signal generating circuit.

11. A method for resetting the semiconductor device of claim 1, wherein a voltage higher than the predetermined voltage is supplied to the first pad to cause the signal generating circuit to output the signal for resetting an internal circuit.
